(19) United States
(12) Patent Application Publication
(10) Pub. No.: US 2011/0006797 A1
(43) Pub. Date: Jan. 13, 2011

(54) PROBE CARD AND TEST EQUIPMENT

(75) Inventor: Hitoshi HIRATSUKA, Kawasaki-shi (JP)

Correspondence Address: SUGHRUE MION, PLLC, 2100 PENNSYLVANIA AVENUE, N.W., SUITE 800, WASHINGTON, DC, 20037, US

(73) Assignee: NEC Electronics Corporation, Kawasaki-shi (JP)

(21) Appl. No.: 12/796,173

(22) Filed: Jun. 8, 2010

(30) Foreign Application Priority Data
Jul. 7, 2009 (JP) 2009-161085

(51) Int. Cl. G01R 31/02; G01R 1/073

(52) U.S. Cl. 324/756.03; 324/762.05; 324/762.06

(57) ABSTRACT

Provided are a probe card including a first area group including a plurality of first areas, each including a plurality of probes for input pad and probes for output pad, the first areas being aligned in L rows by M columns (L, M: natural number); and a second area group including a plurality of second areas, each including a plurality of probes for input pad, the second areas being aligned in (L×N) rows by M columns (N: natural number); and the first area group and the second area group are continuously connected in a column direction according to the chip alignment, such that the first areas and the second areas are aligned in {L+(L×N)} rows by M columns.

This application is based on Japanese patent application No. 2009-161085, the content of which is incorporated hereinto by reference.

### BACKGROUND

1. Technical Field

The present invention relates to a probe card and a test equipment.

2. Related Art

To execute a functional test with respect to each of a plurality of chips formed on a wafer, a probe card is employed for connecting the chips and a tester. Description on the probe card can be found, for example, in JP-A No. H2-189946 and JP-A No. 2004-301807.

The probe card according to JP-A No. H2-189946 is shown in FIG. 8. FIG. 8 depicts a probe card 11 placed at a predetermined position for executing a test with respect to chips 1a to 1d, which are a part of a plurality of chips formed on a wafer. As shown therein, the probe card 11 according to JP-A No. H2-189946 includes a probe array 13 configured to simultaneously contact a respective input/output pad 2 of the chips 1a to 1d. Such structure allows the probe card 11 to simultaneously execute the same test with respect the four chips 1a to 1d.

The probe card according to JP-A No. 2004-301807 is shown in FIG. 9. FIG. 9 depicts a probe card 71 placed at a predetermined position for executing a test with respect to chips 61, 62, which are a part of a plurality of chips formed on a wafer. As shown therein, the probe card 11 according to JP-A No. 2004-301807 includes probes 72a to 72d configured to simultaneously contact a respective input pad 63, 64, and a respective output pad 65, 66 of the chips 61, 62. Such structure allows the probe card 71 to simultaneously execute the same test with respect the two chips 61, 62.

[Patented document 1] JP-A No. H2-189946

[Patented document 2] JP-A No. 2004-301807

FIG. 10 schematically depicts the configuration of the probe card according to the patented documents 1, 2. FIG. 10 only shows the front tip portion of the probes. The probe card shown in FIG. 10 includes an upper and a lower area, each including a plurality of probes for input pad (blank circles in FIG. 10) and a plurality of probes for output pad (solid circles in FIG. 10), aligned so as to correspond to the respective input/output pads. Thus, the probe card shown in FIG. 10 can simultaneously execute the same test with respect to two chips formed on the wafer.

FIG. 11 shows an example of probing sequence to be followed when executing the test with the probe card shown in FIG. 10. As shown in FIG. 11, chips CH are integrated on a wafer WAF by surface-mounting. For the sake of explicitness of the description, row numbers and column numbers are marked according to the alignment of the chips.

In FIG. 11, broken-line arrows indicate the moving direction of the probe card, and a plurality of regions enclosed by bold broken lines represents a first and a last probing position in each column of the probing route (vertical direction in FIG. 11). Also, hatched regions represent a first and a last chip CH in each column among those chips CH that have the chance to pass the test. In other words, the chips CH located at an outer position than the hatched chip CH in the column direction are located at an edge portion of the wafer WAF, which hence have no chance to pass the test, and therefore it is not necessary to execute the test for such chips CH.

When executing the test for the plurality of chips CH formed on the wafer WAF as shown in FIG. 11 utilizing the probe card shown in FIG. 10, the probe card is moved, for example, in the direction indicated by the broken-line arrows in FIG. 11 in increments corresponding to 2 chips, to thereby simultaneously execute the same test with respect to two chips CH at each stop. In this case, the test is executed first for the chips CH located at column No. A and row No. 13 (hereinafter denoted as “A13”, which also applies to other chips CH) and A14, and last for the chips CH located at [H12, H13].

Recently, IC chips with a far greater number of output pads than input pads have been developed, such as an LCD driver. Some have 400 output pads with only 40 input pads. Naturally, the probe card employed for testing such chips include, as shown in FIG. 10, a far greater number of probes for output pad (solid circles) than the probes for input pad (blank circles).

Here, the tester of each test equipment, to be connected to the respective chips through the probe card, has a fixed number of output terminals and input terminals, for example 1280 output terminals and 256 input terminals. In the case of testing the chip having 40 input pads and 400 output pads utilizing such equipment, it appears preferable to simultaneously execute the same test for three chips, from the viewpoint of efficiency in utilizing the output terminals and input terminals of the equipment.

In this case, 1200 (400×3) output terminals of the tester are utilized and 80 are left unused. Likewise, 120 (40×3) input terminals are utilized and 136 are left unused. Thus, while the number of output terminals left unused is smaller than the number of output pads of the chip (smaller than 400), the number of input terminals left unused is greater than the number of input pads of the chip (greater than 40). Such a case that a greater number of input terminals than the input pads of the chip are left unused originates from those chips having a far greater number of output pads than the input pads, such as an LCD driver. The number of input terminals that are unused is increasing, such as the foregoing example in which the input terminals corresponding to three chips (120) are unused. The presence of such large number of unoccupied terminals degrades the utilization efficiency of the test equipment, as well as the testing efficiency with respect to the chips formed on the wafer.

In order to minimize the number of unoccupied terminals, it might be an option to manufacture a new equipment having the output terminals and input terminal in the number corresponding to the output pads and input pads of the chip, however actually it is unrealistic to manufacture expensive equipments for each chip.

### SUMMARY

In one embodiment, there is provided a probe card comprising a first area group including a plurality of first areas, each including a plurality of probes for input pad and probes for output pad located so as to correspond to input pads and output pads of one of a plurality of chips on a wafer to be tested, the first areas being aligned in L rows by M columns (L, M: natural number) according to an alignment of the chips on the wafer to be tested; and a second area group including a plurality of second areas, each including a plurality of probes for input pad located so as to correspond to input pads of one of the chips on the wafer to be tested, the second areas being aligned in (L×N) rows by M columns (N: natural number) or in L rows by (M×N) columns according to the alignment of the chips on the wafer to be tested; wherein in the case where the second area group includes (L×N) rows and M columns the first area group and the second area group are continuously connected in a column direction according to the alignment of the chips, such that the first areas and the second areas are aligned in {L+(L×N)} rows by M columns, and in the case where the second area group includes L rows and (M×N) columns the first area group and the second area group are continuously connected in a row direction according to the alignment of the chips, such that the first areas and the second areas are aligned in L rows by {M+(M×N)} columns.

In another embodiment, there is provided a test method that employs the foregoing probe card for executing a test with respect to each of the chips on the wafer, the test including a first item which exclusively utilizes the input pad and which requires a time t, and a second item which utilizes the input pad and the output pad, comprising moving the probe card in the column direction in increments of L rows with the second area located forward, in the case where the first areas and the second areas are aligned in {L+(L×N)} rows by M columns; moving the probe card in the row direction in increments of M columns with the second area located forward, in the case where the first areas and the second areas are aligned in L rows by {M+(M×N)} columns; and executing, with respect to the chips confronting the second area, the first item for a duration of t/(N+1), and with respect to the chips confronting the first area, the second item after executing the first item for a duration of t/(N+1), at each position reached upon moving the probe card.

By the test method utilizing the probe card according to the present invention, while a predetermined test is executed with respect to the chips confronting the first area, a part of the first item, which requires the time t, is executed with respect to other chips located ahead of the chips confronting the first area in the moving direction of the probe card, utilizing the unoccupied input terminals. Such arrangement allows reducing the duration of the first item, which would otherwise take the time t, with respect to the chips that confront the first area after moving the probe card.

Also, the test method utilizing the probe card according to the present invention dividedly executes the first item in (N+1) times. Accordingly, the duration of the first item at each position reached upon moving the probe card becomes t/(N+1). Since on the other hand the number of travels of the probe card remains substantially unchanged, the time required for successively executing the test with respect to the chips formed on the wafer can be significantly shortened.

Thus, the test method utilizing the probe card according to the present invention allows efficiently utilizing the input terminals and output terminals provided on the tester by minimizing the number of unoccupied terminals, when successively testing the chips formed on the wafer, thereby improving the testing efficiency. Besides, the method allows efficiently executing the successive test with respect to the chips formed on the wafer with minimized time loss, thereby achieving a significant time-saving effect.

In a word, the present invention enables more efficiently executing the successive test with respect to the chips formed on the wafer than ever.

### BRIEF DESCRIPTION OF THE DRAWINGS

The above and other objects, advantages and features of the present invention will be more apparent from the following description taken in conjunction with the accompanying drawings, in which:

FIG. 1 is a schematic plan view showing an example of a probe card according to an embodiment of the present invention;

FIG. 2 is a schematic plan view showing another example of the probe card according to the embodiment;

FIG. 3 is a schematic plan view showing still another example of the probe card according to the embodiment;

FIG. 4 is a flowchart for explaining a test method according to the embodiment;

FIG. 5 is a schematic diagram for explaining a probing sequence of the test method according to the embodiment;

FIG. 6 is a flowchart for explaining a test method according to another embodiment;

FIG. 7 is a schematic diagram for explaining a probing sequence of the test method according to another embodiment;

FIG. 8 is a schematic plan view showing a conventional probe card;

FIG. 9 is a schematic plan view showing another conventional probe card;

FIG. 10 is a schematic plan view of a probe card; and

FIG. 11 is a schematic diagram for explaining a probing sequence of a test method to be executed with respect to a wafer.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereunder, embodiments of the present invention will be described, referring to the drawings. In all the drawings, the same constituents will be given the same numeral, and the description thereof will not be repeated. Hereafter, a vertical direction based on the orientation of the drawings will be referred to as “column direction”, and a horizontal direction of the drawings as “row direction”.

### Embodiment 1

A probe card according to this embodiment is employed with a tester that executes a stress test such as a high-voltage test with respect to chips on a wafer to be tested, and a functional test for checking whether the chips normally operate. More specifically, the probe card is utilized for connecting the chips formed on the wafer to be tested and the tester. The probe card according to this embodiment, as well as a test method that employs the probe card according to this embodiment offer significant advantages when applied to IC chips having a far greater number of output pads than input pads, such as an LCD driver chip.

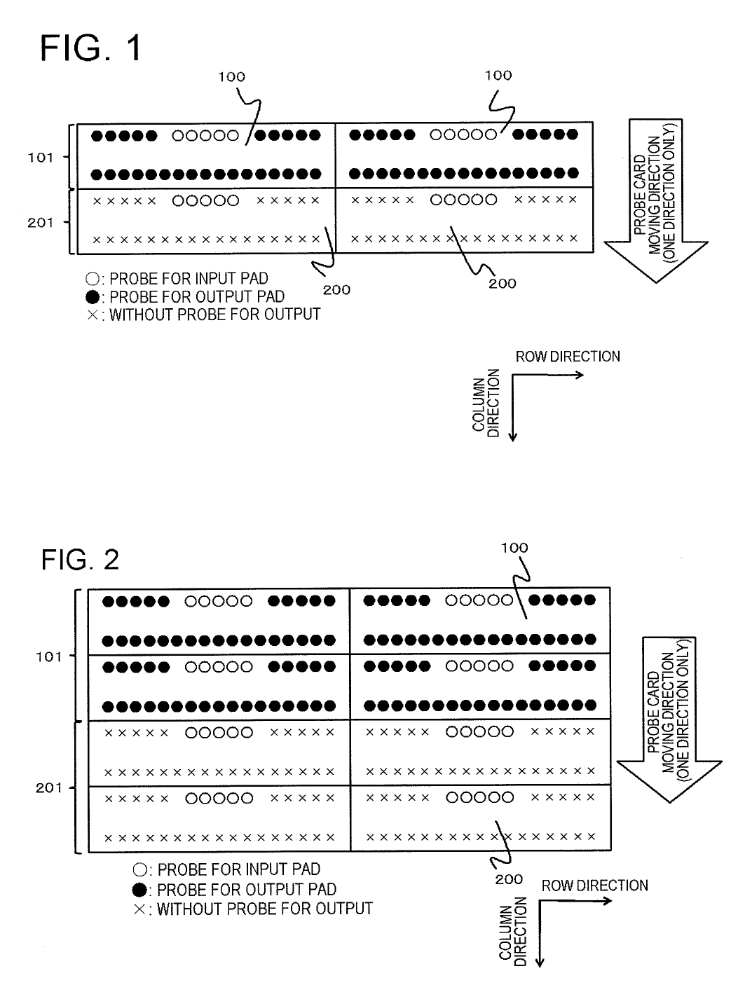

A structure of the probe card according to this embodiment will now be described in details. FIGS. 1 to 3 schematically depict the examples of the probe card according to this embodiment. The drawings only show the front tip portion of the probes.

The probe card according to this embodiment includes a first area group 101 including first areas 100, each including a plurality of probes for input pad (blank circles in FIGS. 1 to 3) and probes for output pad (solid circles in FIGS. 1 to 3) located so as to correspond to input pads and output pads of one of the chips on the wafer to be tested, and the first areas 100 are aligned in L rows by M columns (L, M: natural number) according to the chip alignment on the wafer to be tested.

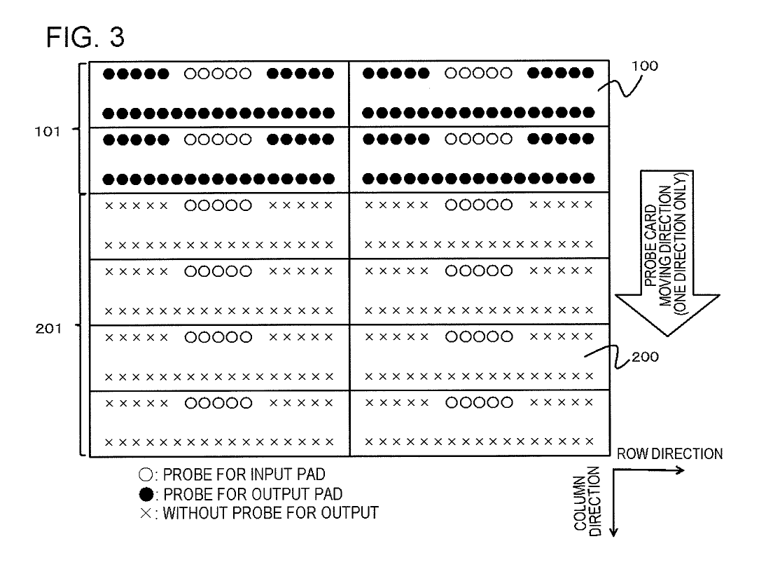

FIG. 1 depicts the first area group 101 in which the first areas 100 are aligned in one row and two columns (L=1, M=2). Likewise, FIGS. 2 and 3 depict the first area group 101 in which the first areas 100 are aligned in two rows by two columns (L=2, M=2). Here, FIGS. 1 to 3 are merely exemplary and different configurations may be adopted.

Also, the probe card according to this embodiment includes a second area group 201 including second areas 200, each including a plurality of probes for input pad (blank circles in FIGS. 1 to 3) located so as to correspond to input pads of the chip on the wafer to be tested, and the second areas 200 are aligned in (L×N) rows by M columns (N: natural number) or in L rows by (M×N) columns, according to the chip alignment on the wafer to be tested. Crosses in FIGS. 1 to 3 indicate that neither the probe for input pad nor the probe for output pad is provided. Thus, the second area 200 mandatorily includes the probes for input pad but does not necessarily have to include the probe for output pad.

FIG. 1 depicts the second area group 201 in which the second areas 200 are aligned in one row by two columns (L=1, M=2, N=1 in (L×N) rows by M columns). Likewise, FIG. 2 depicts the second area group 201 in which the second areas 200 are aligned in two rows by two columns (L=2, M=2, N=1 in (L×N) rows by M columns). FIG. 3 depicts the second area group 201 in which the second areas 200 are aligned in four rows by two columns (L=2, M=2, N=2 in (L×N) rows by M columns). Here too, FIGS. 1 to 3 are merely exemplary and different configurations may be adopted.

In the probe card according to this embodiment, in the case where the second area group 201 includes (L×N) rows and M columns, the first area group 101 and the second area group 201 are continuously connected in the column direction according to the chip alignment, such that the first areas 100 and the second areas 200 are aligned in {L+(L×N)} rows by M columns.

Also, in the case where the second area group 201 includes L rows and (M×N) columns, the first area group 101 and the second area group 201 are continuously connected in the row direction according to the chip alignment, such that the first areas 100 and the second areas 200 are aligned in L rows by {M+(M×N)} columns.

FIG. 1 depicts the case where the second area group 201 includes (L×N) rows and M columns (L=1, M=2, N=1), and the first area group 101 and the second area group 201 are continuously connected in the column direction, such that the first areas 100 and the second areas 200 are aligned in two rows by two columns. FIG. 2 depicts the case where the second area group 201 includes (L×N) rows and M columns (L=2, M=2, N=1), and the first area group 101 and the second area group 201 are continuously connected in the column direction, such that the first areas 100 and the second areas 200 are aligned in four rows by two columns. FIG. 3 depicts the case where the second area group 201 includes (L×N) rows and M columns (L=2, M=2, N=2), and the first area group 101 and the second area group 201 are continuously connected in the column direction, such that the first areas 100 and the second areas 200 are aligned in six rows by two columns. Here, FIGS. 1 to 3 are merely exemplary and different configurations may be adopted.

It is preferable that the probe card thus configured according to this embodiment satisfies the relationship expressed as Cₒ×L×M≦Tₒ and Cᵢ×L×N×M≦Tᵢ, in which Cₒ (natural number) denotes the number of output pads per chip on the wafer to be tested, Cᵢ (natural number) the number of input pads thereof, Tₒ (natural number) the number of output terminals of the tester connected to the respective chips on the wafer to be tested, and Tᵢ (natural number) the number of input terminals thereof. In the case where such relationship is satisfied, there is no first area 100 nor second area 200 that is not utilized for the test of the chip on the wafer, and no probe for input pad nor probe for output pad that is not utilized for the test of the chip on the wafer, and therefore the probe card offers high efficiency. To be more detailed, the probe card offers such advantages as reduction of cost per probe card, higher productivity of the probe card, reduction in size, easier storage and handling during the chip test, and so forth.

Also, it is preferable, in the probe card according to this embodiment, to set L, M, and N at a largest possible value as long as the foregoing relationship is satisfied. Such setting allows improving the testing efficiency when successively executing the test for the chips formed on the wafer.

Now, a test method that utilizes the probe card according to this embodiment will be described hereunder. The test method according to this embodiment is intended for testing the chips formed on the wafer, including a first item which exclusively utilizes the input pad of the chip and which requires a time t, and a second item which utilizes the input pad and the output pad of the chip.

Examples of the first item include a stress test such as a high-voltage test, a connection (open/short) test of the input terminal, and current measurement at an input circuit. The required time t is a design factor to be determined according to the nature of the test, required performance, and so on.

An example of the second item is a functional test of the chip, more specifically a test including inputting a signal through the input pad of the chip, receiving the signal outputted through the output pad, and comparing the output signal with an expected value thereby deciding whether the chip works normally. The second item is executed after completing the first item. For example, the stress test is executed for a predetermined period of time as the first item, and then the functional test is executed as the second item.

By the test method according to this embodiment, in the case where the first areas 100 and the second areas 200 are aligned in {L+(L×N)} rows by M columns, the probe card is moved in the column direction in increments of L rows with the second area 200 located forward. And at each position reached upon moving the probe card, the first item is executed for a duration of t/(N+1) with respect to the chips confronting the second area 200. With respect to the chips confronting the first area 100, the first item is executed for a duration of t/(N+1), after which the second item is executed.

In other words, in the case where the first area group 101 and the second area group 201 are continuously connected in the column direction (aligned in {L+(L×N)} rows by M columns) as shown in FIGS. 1 to 3, the probe card is moved in the column direction (downward based on the orientation of the drawings) in increments of L rows with the second area 200 located forward. In the case of FIG. 1, the probe card is moved downward in increments of one row, and in the case of FIGS. 2 and 3 the probe card is moved downward in increments of 2 rows. And at each position reached upon moving the probe card, the first item is executed for a duration of t/(N+1) with respect to the chips confronting the second area 200. With respect to the chips confronting the first area 100, the first item is executed for a duration of t/(N+1), after which the second item is executed.

By the test method according to this embodiment, likewise, in the case where the first areas 100 and the second areas 200 are aligned in L rows by {M+(M×N)} columns, the probe card is moved in the row direction in increments of M columns with the second area located forward. And at each position reached upon moving the probe card, the first item is executed for a duration of t/(N+1) with respect to the chips confronting the second area 200. With respect to the chips confronting the first area 100, the first item is executed for a duration of t/(N+1), after which the second item is executed.

In other words, in the case where the first area group 101 and the second area group 201 are continuously connected in the row direction (aligned in L rows by {M+(M×N)} columns), the probe card is moved in the row direction in increments of L columns with the second area 200 located forward. And at each position reached upon moving the probe card, the first item is executed for a duration of t/(N+1) with respect to the chips confronting the second area 200. With respect to the chips confronting the first area 100, the first item is executed for a duration of t/(N+1), after which the second item is executed.

By the test method thus arranged according to this embodiment, the test is executed as follows, with respect to any chosen chip among those formed on the wafer (hereinafter, “first chip”). The process of the test will be described hereunder focusing on the first chip.

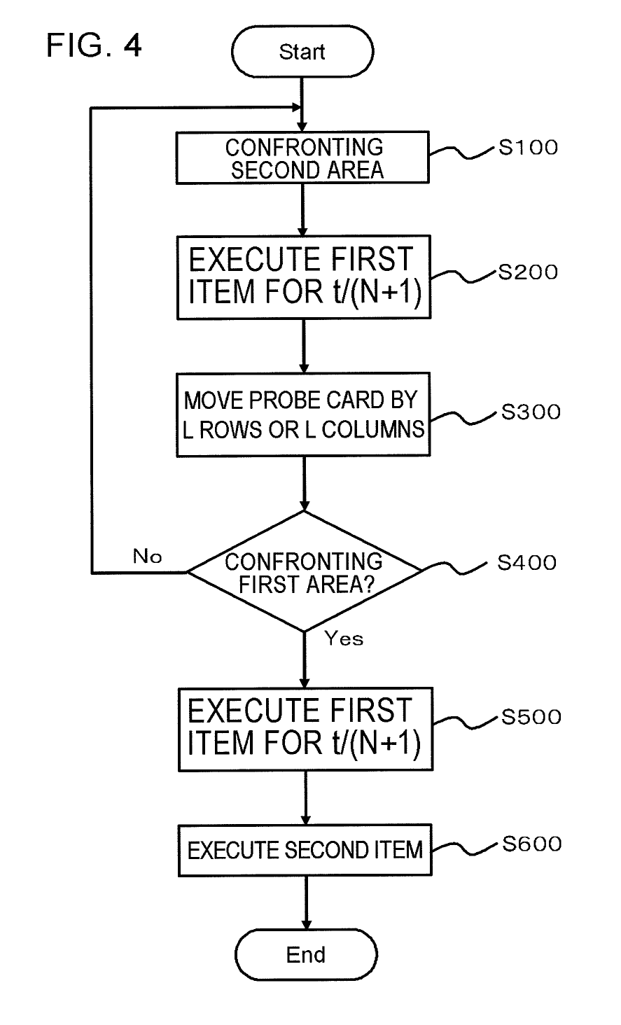

To start with, as shown in the flowchart shown in FIG. 4, the first chip confronts the second area 200 of the probe card (S100). The first chip is then contacted by the probes for input pad provided in the second area 200, and undergoes the first item for a duration of t/(N+1) (S200).

Then the probe card is moved, with the second area 200 located forward, in the column direction by L rows or in the row direction by L columns (S300).

After the probe card has moved, the first chip confronts another second area 200, or the first area 100 of the probe card (S400).

In the case where the first chip confronts another second area 200 (NO at S400), the process returns to 5100 and the steps S100 to S400 are repeated.

On the other hand, in the case where the first chip confronts the first area 100 (YES at S400), the first chip is contacted by the probes for input pad and probes for output pad provided in the first area 100, and undergoes the first item for a duration of t/(N+1). Through this process, the first chip has completely undergone the first item for the entire duration of t (required duration of the first item). In other words, in the case of the stress test for example, the specified amount of stress for the test has been fully imposed on the first chip (S500). Thereafter, the first chip undergoes the second item (S600).

Thus, the first chip undergoes the second item after having dividedly undergone the first item in (N+1) times. Now, the test process to be executed with respect to the first chip will be described, referring to the probe cards shown in FIGS. 1 to 3 as examples.

In the case of employing the probe card shown in FIG. 1, the first chip first confronts the second area 200, and undergoes the first item for a duration of t/2. Upon moving the probe card downward in the drawing by one row, the first chip confronts the first area 100.

The first chip is then contacted by the probes for input pad and probes for output pad provided in the first area 100, and first undergoes the first item for a duration of t/2. Thus, the first chip has completely undergone the first item, which requires the duration of t. Thereafter, the first chip undergoes the second item.

In the case of employing the probe card shown in FIG. 2, the first chip first confronts the second area 200, and undergoes the first item for a duration of t/2. Upon moving the probe card downward by two rows, the first chip confronts the first area 100.

The first chip is then contacted by the probes for input pad and probes for output pad provided in the first area 100, and first undergoes the first item for a duration of t/2. Thus, the first chip has completely undergone the first item, which requires the duration of t. Thereafter, the first chip undergoes the second item.

In the case of employing the probe card shown in FIG. 3, the first chip first confronts the second area 200, and undergoes the first item for a duration of t/3. Upon moving the probe card downward by two rows, the first chip confronts another second area 200, and undergoes the first item for a duration of t/3. Upon moving the probe card again downward by two rows, the first chip confronts the first area 100.

The first chip is then contacted by the probes for input pad and probes for output pad provided in the first area 100, and first undergoes the first item for a duration of t/3. Thus, the first chip has completely undergone the first item, which requires the duration of t. Thereafter, the first chip undergoes the second item.

The test method according to this embodiment enables reducing the number of input terminals of the tester that remain unused for the test, thereby improving the utilization efficiency of the tester. This leads to higher testing efficiency with respect to the chips formed on the wafer. Here, although the test method according to this embodiment divides the first item, which requires the duration of t, in (N+1) times, in the case where the first item is the stress test, dividing the stress application in a plurality of times incurs no problem from the viewpoint of test specification, as long as the total time of stress application is secured. In the case where the total time of stress application is the same, applying the stress a greater number of times may rather be preferable for the purpose of the test.

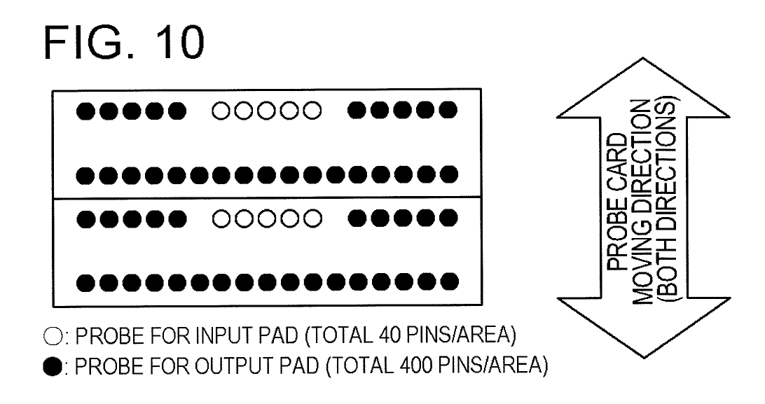

Now, the following is a description on comparison of actual time between the tests executed with the probe card shown in FIG. 10 and with the probe card shown in FIG. 1 representing this embodiment, both executed with a popularly employed tester.

### With the Probe Card Shown in FIG. 1 Representing this Embodiment

The probe card shown in FIG. 1 includes two areas (first areas 100), each including the probes for input pad and probes for output pad, to thereby simultaneously execute the same test with respect to two chips. The probe card also includes two areas (second areas 200), each including the probes for input pad, in order to efficiently utilize the input terminals of the tester that may otherwise remain unoccupied.

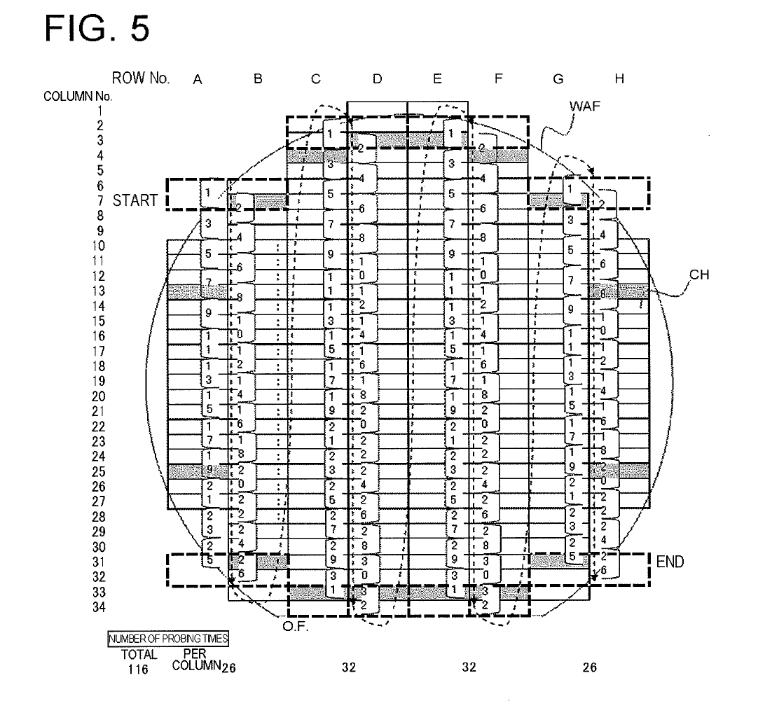

FIG. 5 shows an example of the probing sequence to be followed when executing the test with the probe card shown in FIG. 1. As shown therein, the chips CH are integrated on the wafer WAF by surface mounting. For the sake of explicitness of the description, row numbers and column numbers are marked according to the alignment of the chips.

In FIG. 5, broken-line arrows indicate the moving direction of the probe card, and a plurality of regions enclosed by bold broken lines represents a first and a last probing position in the probing route in the column direction (vertical direction in FIG. 5). Also, hatched regions represent a first and a last chip CH in the column direction among those chips CH that have the chance to pass the test. In other words, the chips CH located at an outer position than the hatched chip CH in the column direction are located at an edge portion of the wafer WAF, which hence have no chance to pass the test, and therefore it is not necessary to execute the test for such chips CH.

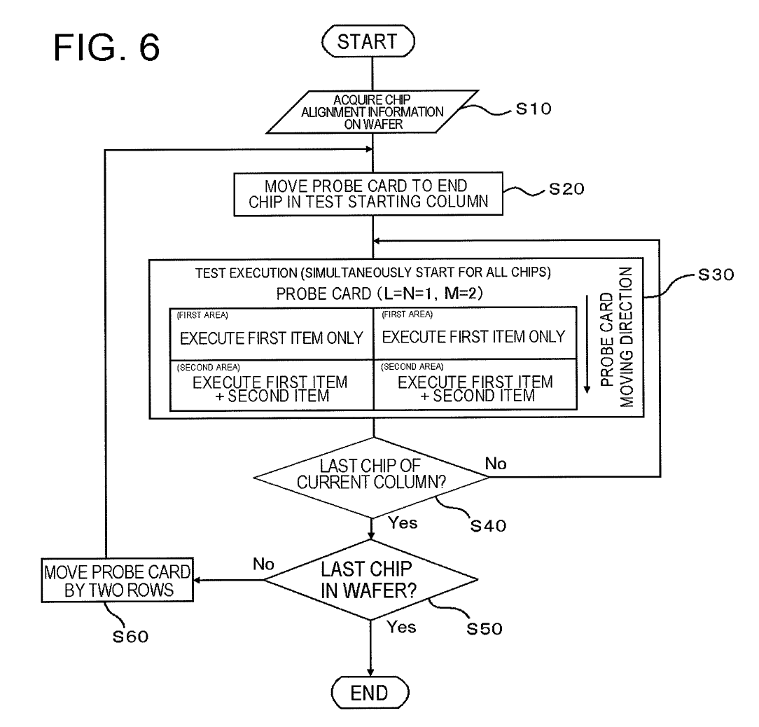

Referring now to the flowchart shown in FIG. 6, description will be given on the test process including a first item and a second item, to be executed with respect to a wafer shown in FIG. 5 with the probe card shown in FIG. 1.

First, the test equipment including the probe card shown in FIG. 1 and the tester acquires alignment information of the chips CH formed on the wafer WAF to be tested (S10).

Then the column from which the test is to be started is identified based on the alignment information acquired at the step S10. Referring to FIG. 5, the columns A and B are identified. Then the position where the probe card is to be first located is determined. More particularly, the chip CH located at an end portion in the column direction is identified among the chips CH that have the chance to pass the test in the columns A and B (in FIG. 5 the chip CH in the row of a smallest number), and the first position of the probe card is determined such that the second area 200 (Ref. FIG. 1) confronts the chip CH thus identified. In FIG. 5, the position at the column No. B and row No. 7 ((hereinafter denoted as “B7”, which also applies to other chips CH) is determined as the position where the second area 200 is to be located. Then the probe card is moved to the position thus determined (S20).

The first item is then executed with respect to the chips CH [A7, B7] confronting the second area 200, for a duration of t/2. After that, the probe card is moved downward based on the orientation of the drawing, by one row. At this stage, the second area 200 of the probe card confronts the chips CH [A8, B8], and the first area 100 (Ref. FIG. 1) confronts the chips CH [A7, B7]. With respect to the chips CH [A8, B8] confronting the second area 200, the first item is executed for a duration of t/2. Meanwhile, with respect to the chips CH [A7, B7] confronting the first area 100, the first item is executed for a duration of t/2, which is followed by the second item. Here, the first item is generally simultaneously started and finished, with respect to the chips CH [A7, B7] and the chips CH [A8, B8]. Thereafter, the second item is executed with respect to the chips CH [A8, B8] (S30).

Then the process of the step S30 is repeated until the second item is executed with respect to the last chip CH of the column undergoing the test. In other words, the process is repeated until the second item is executed with respect to the chip CH located at the other end portion in the column direction among those chips CH that have the chance to pass the test in the columns A and B (in FIG. 5, the chip CH in the row of a largest number). In FIG. 5, thus, the process is repeated until the second item is executed with respect to the chip CH B31. Once it is decided that the second item has been executed with respect to the last chip CH of the column undergoing the test (YES at S40), the process advances to the step S50.

At the step S50, it is decided whether the second item has been executed with respect to the last chip CH among those chips CH that have the chance to pass the test on the wafer. In other words, it is decided whether the second item has been executed with respect to the last chip CH identified based on the alignment information acquired at the step S10 (in the wafer WAF shown in FIG. 5, the chip CH at G31) (S50).

In the case where it is decided that the second item has not yet been executed with respect to the last chip CH (NO at S50), the probe card is moved in the row direction by two columns, so as to confront the columns C and D (S60). Then the chip CH located at an end portion in the column direction and closest to the current position among those chips CH that have the chance to pass the test in the columns C and D (in FIG. 5, the chip CH in the row of a largest number) is identified, and the position where the second area 200 of the probe card confronts the chip CH thus identified is determined. In FIG. 5, such position corresponds to [C33, D33], and the probe card is moved thereto (S20).

The foregoing process is then repeated, and once it is decided that the second item has been executed with respect to the last chip CH (in FIG. 5, the chip CH at G31) (YES at S50), the process is finished.

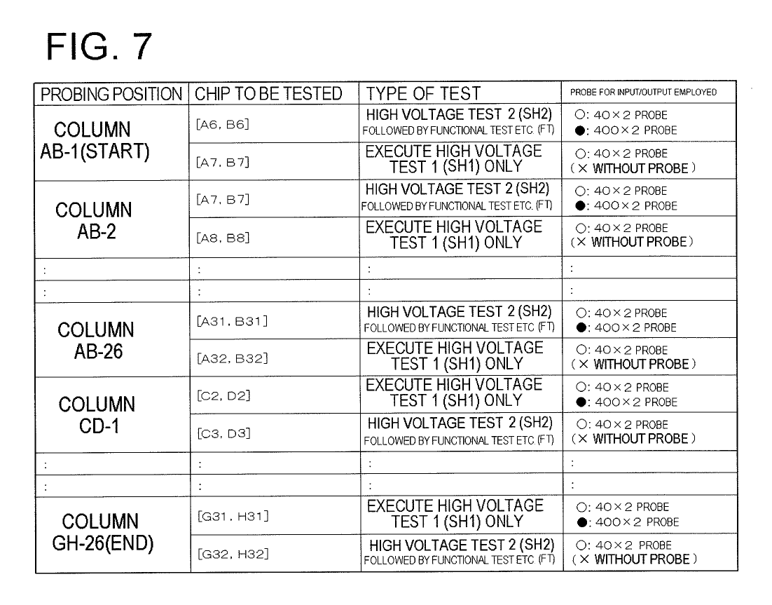

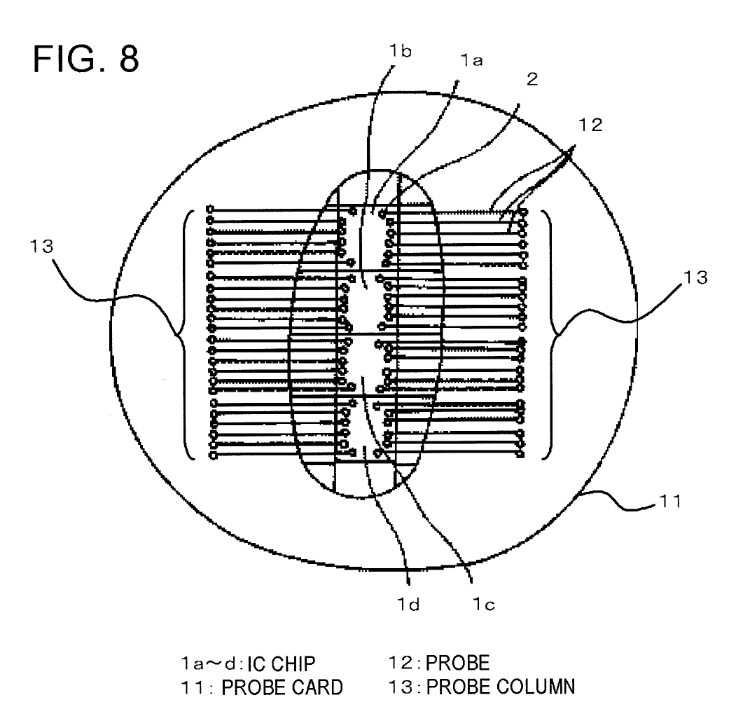

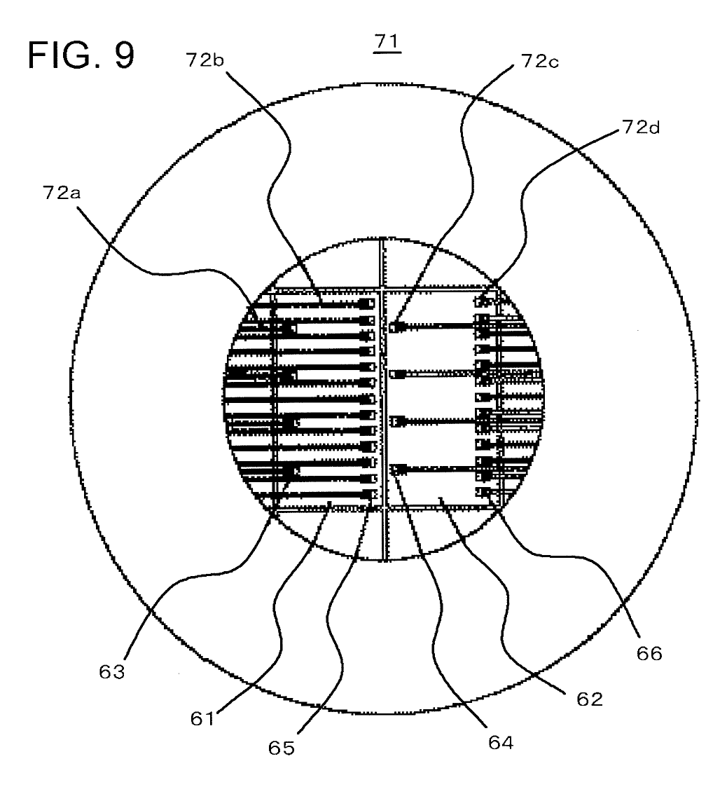

For reference purpose, FIG. 7 shows a table indicating the locating sequence of the probe card in the foregoing process, the column numbers and row numbers of the chips CH confronting the probe card at each position, and the type of the test executed with respect to each of the chips CH. In this case, the probing has been executed 116 times.

Here, since the first item (stress test) is divided into two stages, the total testing time T per wafer with the probe card shown in FIG. 1 can be expressed as (0.1a+5a+1a)×116=707.6a, in which the average probing time is denoted by tP=0.1a, the required time of the first item (stress test) by tₛ=10a, the required time of the second item (functional test) by t_{F}=1a.

[With the Probe Card Shown in FIG. 10]

The probe card shown in FIG. 10 includes two areas, each including the probes for input pad and probes for output pad, to thereby simultaneously execute the same test with respect to two chips.

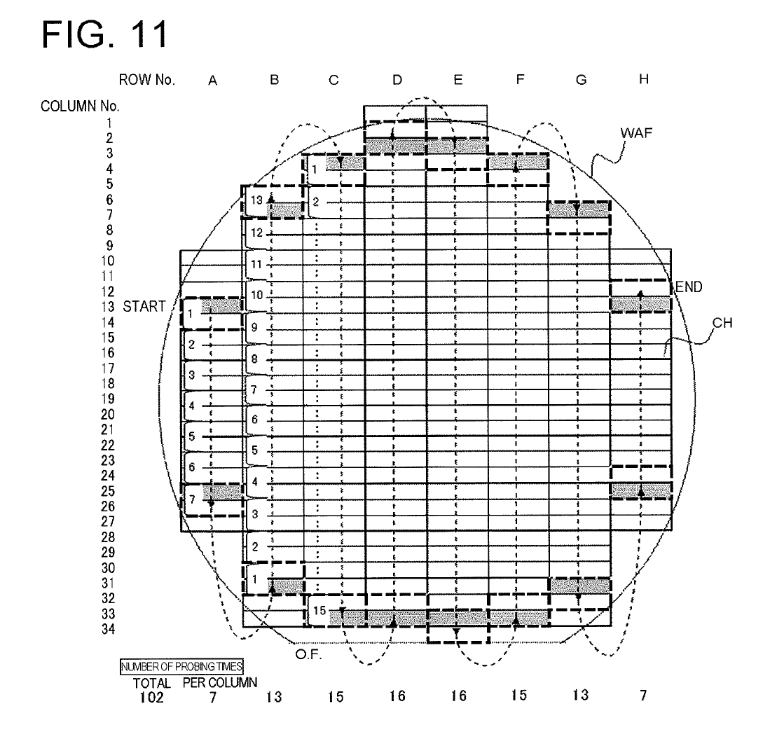

FIG. 11 shows an example of the probing sequence to be followed when executing the test with the probe card shown in FIG. 10. As shown therein, the chips CH are integrated on the wafer WAF by surface mounting. For the sake of explicitness of the description, row numbers and column numbers are marked according to the alignment of the chips.

In FIG. 11, broken-line arrows indicate the moving direction of the probe card, and a plurality of regions enclosed by bold broken lines represents a first and a last probing position in the probing route in the column direction (vertical direction in FIG. 11). Also, hatched regions represent a first and a last chip CH in the column direction among those chips CH that have the chance to pass the test. In other words, the chips CH located at an outer position than the hatched chip CH in the column direction are located at an edge portion of the wafer WAF, which hence have no chance to pass the test, and therefore it is not necessary to execute the test for such chips CH.

The wafer WAF shown in FIG. 11 carries the same chip alignment as that of the wafer shown in FIG. 5. Accordingly, the number of chips CH, the number of those that have the chance to pass the test, and the location of those chips CH are the same as the wafer shown in FIG. 5.

In the case of executing the test with the probe card shown in FIG. 10 in the probing sequence shown in FIG. 11, the test is first executed with respect to the two chips at [A13, A14], and last executed with respect to the two chips at [H12, H13]. In this case, the probing is executed 102 times.

Here, the total testing time T per wafer can be expressed as (0.1a+10a+1a)×102=1132.2a, in which the average probing time is denoted by tP=0.1a, the required time of the first item (stress test) by tₛ=10a, the required time of the second item (functional test) by t_{F}=1a.

The foregoing comparison proves that the total testing time T per wafer with the probe card shown in FIG. 1 representing this embodiment (707.6a) is approx. 62% of the total testing time T per wafer with the probe card shown in FIG. 10 (1132.2a), from which it is apparent that the probe card shown in FIG. 1 significantly shortens the testing time.

By the test method according to this embodiment, while the first item and the second item are being executed with respect to the chip confronting the first area 100, the first item, which requires a duration of t, is executed for a duration of t/(N+1) with respect to another chip located ahead of the chip confronting the first area 100 in the moving direction of the probe card and confronting the second area 200. The divided duration t/(N+1) is determined according to the number of second areas, such that upon executing the first item after moving the probe card for the divided duration of t/(N+1) with respect to the chip confronting the first area 100, the total duration that such chip has undergone the first item becomes t.

By the test method that employs the probe card according to this embodiment, the testing time at each position reached upon moving the probe card can be proportionally shortened according to the number of divided times of the first item. To be more detailed, by the test method that employs the probe card shown in FIG. 10, i.e. by the conventional test method that leaves a part of the input terminals of the tester unoccupied, the first item requires the testing time t at each position reached upon moving the probe card. In contrast, by the test method that employs the probe card according to this embodiment, the first item only takes the testing time t/(N+1) at each position reached upon moving the probe card. Thus, the test method that employs the probe card according to this embodiment shortens the testing time by t−(t/(N+1)).

Under such premise, in the case where the number of “areas where the probes for input pad and probes for output pad are provided” is the same in the probe card employed for the conventional test method and in the probe card employed for the test method according to this embodiment, the number of probing times is substantially the same as described above, and therefore the time required for successively executing the test with respect to the chips formed on the wafer can be significantly shortened.

It is to be noted that the test method according to this embodiment allows, even in the case where the probe card has a different configuration from FIG. 1, executing the test that includes the first item and the second item with respect to the chips formed on the wafer according to the steps of the flowchart shown in FIG. 6. Also, even in the case where the probe card has a different configuration from FIG. 1, the significant reduction in testing time can equally be achieved.

Further, the test method according to this embodiment may be realized as a program for executing a test that employs the probe card according to this embodiment with respect to the chips formed on the wafer to be tested, the test including a first item which exclusively utilizes the input pad of the chip and which requires a time t, and a second item which utilizes the input pad and the output pad of the chip, comprising causing a computer to execute a process including moving the probe card in the column direction in increments of L rows with the second area 200 located forward, in the case where the first areas 100 and the second areas 200 are aligned in {L+(L×N)} rows by M columns; moving the probe card in the row direction in increments of M columns with the second area 200 located forward, in the case where the first areas 100 and the second areas 200 are aligned in L rows by {M+(M×N)} columns; and executing, with respect to the chips confronting the second area 200, the first item for a duration of t/(N+1), and with respect to the chips confronting the first area 100, the second item after executing the first item for a duration of t/(N+1), at each position reached upon moving the probe card. This program may be stored in an information storage medium such as a CD.

### Embodiment 2

The probe card according to this embodiment is generally the same as that of the foregoing embodiment, with a difference in that N should mandatorily be a natural number equal to or greater than 2.

The test method that employs the probe card according to this embodiment is generally the same as that of the foregoing embodiment, and which exclusively utilizes the input pad of the chip and which requires the time t is divided into N times. With respect to the chip confronting the second area 200 of the probe card, the first item is executed for a duration of t/N, and with respect to the chip confronting the first area 100, only the second item is executed.

The moving direction of the probe card and other arrangement of the test method according to this embodiment are similar to those of the foregoing embodiment. Accordingly, detailed description will not be repeated.

By the test method according to this embodiment, the test is executed as follows with respect to any chosen chip among those formed on the wafer (hereinafter, “first chip”). The process of the test will be described hereunder focusing on the first chip.

To start with, the first chip confronts the second area 200 of the probe card. The first chip is then contacted by the probes for input pad provided in the second area 200, and undergoes the first item for a duration of t/N.

Then the probe card is moved, with the second area 200 located forward, in the column direction by L rows, or in the row direction by L columns.

After the probe card has moved, the first chip confronts another second area 200, or the first area 100 of the probe card. The first chip is then contacted by the probes for input pad provided in the second area 200, and undergoes the first item for a duration of t/N.

Thereafter, the probe card is moved, with the second area 200 located forward, in the column direction by L rows, or in the row direction by L columns (in the same direction as the preceding movement).

After the probe card has moved, the first chip confronts another second area 200, or the first area 100 of the probe card.

In the case where the first chip confronts another second area 200, the probe card is moved again as above, and the first chip undergoes the first item for a duration of t/N. This step is repeated until the first chip confronts the first area 100.

On the other hand, in the case where the first chip confronts the first area 100, the first chip is contacted by the probes for input pad and probes for output pad provided in the first area 100, and undergoes the second item.

Thus, the first chip undergoes the second item after having dividedly undergone the first item in N times. Now, the test process to be executed with respect to the first chip will be described, referring to the probe card shown in FIG. 3 as the example.

In the case of employing the probe card shown in FIG. 3, the first chip first confronts the second area 200, and undergoes the first item for a duration of t/2. Upon moving the probe card downward based on the orientation of the drawing by two rows, the first chip confronts another second area 200, and undergoes the first item for a duration of t/2. Through this process, the first chip has completely undergone the first item for the entire duration of t. In other words, in the case where the first item is the stress test, the specified amount of stress for the test has been fully imposed on the first chip.

Then upon moving the probe card downward by two rows, the first chip confronts the first area 100. The first chip is contacted by the probes for input pad and probes for output pad provided in the first area 100, and undergoes the second item.

The probe card and the test method according to this embodiment enable reducing the number of input terminals of the tester that remain unused for the test, thereby improving the utilization efficiency of the tester. This leads to higher testing efficiency with respect to the chips formed on the wafer. Also, the time required for successively executing the test with respect to the plurality of chips formed on the wafer can be significantly shortened.

Further, the test method according to this embodiment may be realized as a program for executing a test that employs the probe card according to this embodiment with respect to the chips formed on the wafer to be tested, the test including a first item which exclusively utilizes the input pad of the chip and which requires a time t, and a second item which utilizes the input pad and the output pad of the chip, comprising causing a computer to execute a process including moving the probe card in the column direction in increments of L rows with the second area 200 located forward, in the case where the first areas 100 and the second areas 200 are aligned in {L+(L×N)} rows by M columns; moving the probe card in the row direction in increments of M columns with the second area 200 located forward, in the case where the first areas 100 and the second areas 200 are aligned in L rows by {M+(M×N)} columns; and executing, with respect to the chips confronting the second area 200, the first item for a duration of t/N, and with respect to the chips confronting the first area 100, the second item after executing the first item for a duration of t/N, at each position reached upon moving the probe card. This program may be stored in an information storage medium such as a CD.

It is apparent that the present invention is not limited to the above embodiment, and may be modified and changed without departing from the scope and spirit of the invention.

The present invention also includes the following features.
(1) A probe card including:

a first area group including a plurality of first areas, each including a plurality of probes for input pad and probes for output pad located so as to correspond to input pads and output pads of one of a plurality of chips on a wafer to be tested, the first areas being aligned in L rows by M columns (L, M: natural number) according to an alignment of the chips on the wafer to be tested; and a second area group including a plurality of second areas, each including a plurality of probes for input pad located so as to correspond to input pads of one of the chips on the wafer to be tested, the second areas being aligned in (L×N) rows by M columns (N: natural number) or in L rows by (M×N) columns according to the alignment of the chips on the wafer to be tested;

wherein in the case where the second area group includes (L×N) rows and M columns,

the first area group and the second area group are continuously connected in a column direction according to the alignment of the chips, such that the first areas and the second areas are aligned in {L+(L×N)} rows by M columns; and

in the case where the second area group includes L rows and (M×N) columns, the first area group and the second area group are continuously connected in a row direction according to the alignment of the chips, such that the first areas and the second areas are aligned in L rows by {M+(M×N)} columns.

A test method that employs the above prove card,

for executing a test with respect to each of the chips on the wafer, including,

a first item which exclusively utilizes the input pad and which requires a time t, and

a second item which utilizes the input pad and the output pad,

the test method including:

moving the probe card in a column direction in increments of L rows with the second area located forward, in the case where the first areas and the second areas are aligned in {L+(L×N)} rows by M columns;

moving the probe card in a row direction in increments of M columns with the second area located forward, in the case where the first areas and the second areas are aligned in L rows by {M+(M×N)} columns; and executing, with respect to the chips confronting the second area, the first item for a duration of t/(N+1), and

with respect to the chips confronting the first area, the second item after executing the first item for a duration of t/(N+1),

at each position reached upon moving the probe card.
(2) In the above test method, the first item may be a high-voltage test.
(3) In the above test method, the chip may be a LCD driver.
(4) An information storage medium storing a program for executing a test that employs the above probe card with respect to the chips formed on the wafer to be tested, the program including:

the test including a first item which exclusively utilizes the input pad of the chip and which requires a time t, and

a second item which utilizes the input pad and the output pad of the chip,

the program including causing a computer to execute a process including:

moving the probe card in a column direction in increments of L rows with the second area 200 located forward, in the case where the first areas 100 and the second areas 200 are aligned in {L+(L×N)} rows by M columns;

moving the probe card in a row direction in increments of M columns with the second area 200 located forward, in the case where the first areas 100 and the second areas 200 are aligned in L rows by {M+(M×N)} columns; and

executing, with respect to the chips confronting the second area, the first item for a duration of t/(N+1), and

with respect to the chips confronting the first area, the second item after executing the first item for a duration of t/(N+1),

at each position reached upon moving the probe card.
(5) A probe card including:

a first area group including a plurality of first areas, each including a plurality of probes for input pad and probes for output pad located so as to correspond to input pads and output pads of one of a plurality of chips on a wafer to be tested, the first areas being aligned in L rows by M columns (L, M: natural number) according to an alignment of the chips on the wafer to be tested; and

a second area group including a plurality of second areas, each including a plurality of probes for input pad located so as to correspond to input pads of one of the chips on the wafer to be tested, the second areas being aligned in (L×N) rows by M columns (N: a natural number equal to or greater than 2) or in L rows by (M×N) columns according to the alignment of the chips on the wafer to be tested;

wherein in the case where the second area group includes (L×N) rows and M columns,

the first area group and the second area group are continuously connected in a column direction according to the alignment of the chips, such that the first areas and the second areas are aligned in {L+(L×N)} rows by M columns; and

in the case where the second area group includes L rows and (M×N) columns, the first area group and the second area group are continuously connected in a row direction according to the alignment of the chips, such that the first areas and the second areas are aligned in L rows by {M+(M×N)} columns.

A test method that employs the above probe card,

for executing a test with respect to each of the chips on the wafer, including,

a first item which exclusively utilizes the input pad and which requires a time t, and

a second item which utilizes the input pad and the output pad,

the test method including:

moving the probe card in a column direction in increments of L rows with the second area located forward, in the case where the first areas and the second areas are aligned in {L+(L×N)} rows by M columns;

moving the probe card in a row direction in increments of M columns with the second area located forward, in the case where the first areas and the second areas are aligned in L rows by {M+(M×N)} columns; and

executing, with respect to the chips confronting the second area, the first item for a duration of t/N, and

with respect to the chips confronting the first area, the second item after executing the first item for a duration of t/N,

at each position reached upon moving the probe card.
(6) In the above test method, the first item may be a high-voltage test.
(7) In the above test method, the chip may be a LCD driver.
(8) An information storage medium storing a program for executing a test that employs the above probe card with respect to the chips formed on the wafer to be tested, the program including:

the test including a first item which exclusively utilizes the input pad of the chip and which requires a time t, and

a second item which utilizes the input pad and the output pad of the chip,

the program including causing a computer to execute a process including:

moving the probe card in a column direction in increments of L rows with the second area 200 located forward, in the case where the first areas 100 and the second areas 200 are aligned in {L+(L×N)} rows by M columns;

moving the probe card in a row direction in increments of M columns with the second area 200 located forward, in the case where the first areas 100 and the second areas 200 are aligned in L rows by {M+(M×N)} columns; and

executing, with respect to the chips confronting the second area, the first item for a duration of t/N, and

with respect to the chips confronting the first area, the second item after executing the first item for a duration of t/N,

at each position reached upon moving the probe card.

What is claimed is:

1. A probe card comprising:
a first area group including a plurality of first areas, each including a plurality of probes for input pad and probes for output pad located so as to correspond to input pads and output pads of one of a plurality of chips on a wafer to be tested, said first areas being aligned in L rows by M columns (L, M: natural number) according to an alignment of said chips on said wafer to be tested; and
a second area group including a plurality of second areas, each including a plurality of probes for input pad located so as to correspond to input pads of one of said chips on said wafer to be tested, said second areas being aligned in (L×N) rows by M columns (N: natural number) or in L rows by (M×N) columns according to said alignment of said chips on said wafer to be tested;
wherein in the case where said second area group includes (L×N) rows and M columns,
said first area group and said second area group are continuously connected in a column direction according to said alignment of said chips, such that said first areas and said second areas are aligned in {L+(L×N)} rows by M columns; and
in the case where said second area group includes L rows and (M×N) columns,
said first area group and said second area group are continuously connected in a row direction according to said alignment of said chips, such that said first areas and said second areas are aligned in L rows by {M+(M×N)} columns.

2. The probe card according to claim 1,
wherein a relationship expressed as Cₒ×L×M≦Tₒ and Cᵢ×L×N×M≦Tᵢ is satisfied,
in which Cₒ (natural number) denotes a quantity of output pads per chip on said wafer to be tested and Cᵢ (natural number) a quantity of input pads thereof, and
Tₒ (natural number) a quantity of output terminals of a tester connected to the respective chips on said wafer to be tested and Tᵢ (natural number) a quantity of input terminals thereof.

3. The probe card according to claim 1, wherein said chip is an LCD driver.

4. A test equipment comprising said probe card according to claim 1 and a tester connected to said chips on said wafer through said probe card.
